(19) United States
(12) Patent Application Publication
(10) Pub. No.: US 2014/0343883 A1
(43) Pub. Date: Nov. 20, 2014

(54) User Interface for Signal Integrity Network Analyzer

(71) Applicant: Teledyne LeCroy, Inc., Thousand Oaks, CA (US)

(72) Inventors: Jonathan Libby, Gray, ME (US); Hitesh Patel, Pompton Lakes, NJ (US); Peter J. Pupalaikis, Ramsey, NJ (US); David C. Graef, Campbell Hall, NY (US); Kaviyesh B. Doshi, Emerson, NJ (US)

(73) Assignee: Teledyne LeCroy, Inc., Thousand Oaks, CA (US)

(21) Appl. No.: 13/894,659

(22) Filed: May 15, 2013

(51) Int. Cl. G01R 1/02; G01R 13/02

(52) U.S. Cl. CPC G01R 1/025; G01R 13/02
USPC 702/68

(57) ABSTRACT

A graphical user interface for use with a signal integrity network analyzer is provided. The user interface may include a selection for selectively enforcing one or more of passivity, reciprocity and causality in one or more measurements by the signal integrity network analyzer. The user interface may include a recalculate selection, wherein after analysis of a calculated waveform, one or more system parameters may be modified, and the previously acquired waveform is again analyzed without acquisition of any additional waveform data in accordance with the one or more modified system parameters. The user interface may include a selection for configuring a number of ports for a device under test to be employed by the signal integrity network analyzer. The user interface may include a selection for autoparking one or more relays associated with the signal integrity network analyzer.

### CROSS REFERENCE TO RELATED APPLICATIONS

This application is a divisional application of U.S. patent Ser. No. 12/892,094 filed Sep. 28, 2010, titled “User Interface for Signal Integrity Network Analyzer”, currently pending, which in turn claims the benefit of U.S. Provisional Patent Application Ser. No. 61/299,512 “User Interface for Time Domain Network Analyzer”, filed Jan. 29, 2010, the entire contents of these applications being incorporated herein by reference.

### FIELD OF THE INVENTION

This invention is related generally to a method and apparatus for operation of a Signal Integrity Network Analyzer, and more particularly to features associated with a user interface thereof.

### BACKGROUND OF THE INVENTION

A TDR (Time Domain Reflectometry) system measures the reflections of an incident waveform from impedance discontinuities in a system under test. Typical TDR systems may include sonar to detect underwater objects, ultrasound to detect objects inside the body and as described in this invention, voltage steps to detect discontinuities in electrical systems. A Signal Integrity Network Analyzer constructed in accordance with various embodiments of the invention may comprise a system that employs such a TDR technology in order to analyze one or more functions of a network. In particular, such a Signal Integrity Network Analyzer may determine one or more scattering parameters (s-parameters) associated with a particular network configuration and architecture.

The primary object of network analysis is to characterize devices. A secondary object is to present device characterization data in a useful manner. The primary object is generally accomplished by stimulating a device in a variety of ways and measuring the responses of the device to such stimuli. The stimuli may be applied in a manner such that the stimuli are known, the stimulation conditions are known, and measurements are made of the response of the device to these known stimuli. Thus, provided a sufficient set of known stimuli and known responses of devices to this stimuli, an entire set of device characteristics can be generated.

Traditionally, such network analyzer functions have been performed through the use of a Vector Network Analyzer (VNA). However, VNAs are very expensive and have a very involved and difficult operation sequence to perform particular network analyzation functions, such as determining the s-parameters of a particular network configuration or device under test. This is primarily because such a VNA is designed to perform a great number of functions, but does not perform these functions according to an easy user interface, and thus fails to offer a number of pre and post measurement functions particularly directed to s-parameter determination and signal analysis.

A VNA is generally designed to determine device characteristics in the form of s-parameters. The stimuli used by a vector network analyzer may be in the form of incident waves and the measurements made may be in the form of reflected waves. While a VNA technically defines an instrument that provides complex (i.e. vectorial) port-port responses at given frequencies, it has come to be associated with a very specific type of instrument from the stand-point of how it measures s-parameters. VNA measurements may be made at various frequencies using swept sine waves, and various methods may be utilized to determine the incident and reflected waves from measurements of standing sinusoidal waves at various frequencies.

The industry has standardized on s-parameter measurements and therefore it is desirable that VNAs and TDNAs (Time Domain Network Analyzers) measure s-parameters.

Because of the manner in which VNAs are built, they tend to be very expensive instruments. They tend to be so expensive as to be prohibitive in cost to all but those who desperately need one. The cost increases with the availability of higher frequency performance and an increase in the number of available ports.

Today, signal integrity is a field that involves the design and analysis of high speed systems. As of late, the speeds have become so high as to blend into the microwave domain—the traditional domain employing VNAs. As of this writing, 5-10% of VNAs are used for signal integrity analysis, again to only those who can afford such instruments. It is useful to remember that while the domain of the microwave engineer is usually the frequency domain, the effects of interest to a signal integrity engineer are usually in the time domain.

The traditional VNA has some features making it more difficult to operate. One is the requirement for calibration. Calibration of a VNA is traditionally performed by connecting known devices called standards to the ports of the VNA under various measurement conditions. The measurements made during calibration coupled with the knowledge of the characteristics of the standards are employed to measure error-terms that are used to correct the actual measurements of a device-under-test (DUT). Generally, the reference plane of the VNA is the end of cables, precisely where the DUT connects to the instrument and therefore calibration involves connection and disconnection of the standards and device under test from and to the instrument. This connection and disconnection is time consuming and increases the chances of error.

Therefore it would be beneficial to provide an improved method and apparatus that overcomes the drawbacks of the prior art, and in particular provide a time-domain network analysis instrument and method that are capable of measuring s-parameters while overcoming the drawbacks of the prior art.

Still other objects and advantages of the invention will in part be obvious and will in part be apparent from the specification and the drawings.

### SUMMARY OF THE INVENTION

In accordance with the invention, a test and measurement apparatus comprising a Signal Integrity Network Analyzer (SINA) is provided having a user interface including a plurality of properties making network analyzer functions, such as determining s-parameters for a particular network topology and calibration, easy for a user to perform.

Therefore, in accordance with the invention, a method and apparatus are provided that provide for a better user experience when analyzing a network topology, and in particular when determining s-parameters for a particular network topology or device under test.

The invention accordingly comprises the features of construction, combination of elements, and arrangement of parts which will be exemplified in the construction hereinafter set forth.

### BRIEF DESCRIPTION OF THE DRAWINGS

For a more complete understanding of the invention, reference is made to the following description and accompanying drawings, in which:

FIG. 1 is a depiction of a menu selection for selecting a desired level of processing in accordance with an embodiment of the invention;

FIG. 2 depicts the selection menu of FIG. 1 in main setup dialog display;

FIG. 3 depicts a more advanced setup menu in accordance with an embodiment of the invention;

FIG. 4 depicts a calibration setup menu in accordance with an embodiment of the invention;

FIG. 5 depicts a results analysis feature for measuring a magnitude of an s-parameter at a specific frequency in accordance with an embodiment of the invention;

FIG. 6 depicts a results analysis feature for measuring a maximum value for a desired parameter within a gated range of s-parameter results in accordance with an embodiment of the invention;

FIG. 7 depicts a results action setup menu in accordance with an embodiment of the invention;

FIG. 8 depicts an s-parameter result import menu in accordance with an embodiment of the invention;

FIG. 9 depicts a measurement procedure selection menu in accordance with an embodiment of the invention;

FIG. 10 depicts an eye view embedding measured s-parameters in accordance with an embodiment of the invention;

FIG. 11 depicts a processing web editor definition for providing such an eye view embedding the measured s-parameters of FIG. 10;

FIG. 12 reflects an impedance profile of a device under test over time in accordance with an embodiment of the invention;

FIG. 13 depicts the various frequency and time domain types for the s-parameter results in accordance with an embodiment of the invention;

FIG. 14 depicts a result display setup menu in accordance with an embodiment of the invention;

FIG. 15 depicts an instrument setup menu in accordance with an embodiment of the invention;

FIG. 16 depicts a sub menu for providing a further break down of estimated processing time in accordance with an embodiment of the invention;

FIG. 17 depicts a relay settings display in accordance with an embodiment of the invention;

FIG. 18 depicts a relay parking menu in accordance with an embodiment of the invention;

FIG. 19 depicts a ports configuration display in accordance with an embodiment of the invention;

FIG. 20 depicts a Smith Chart display and configuration dialog in accordance with an embodiment of the invention; and

FIG. 21 depicts an error band associated with an s-parameter measurement graph in accordance with an embodiment of the invention.

### DETAILED DESCRIPTION OF THE PREFERRED EMBODIMENTS

In a traditional s-parameter measurement instrument such as a VNA or the like, and as noted above, calibration of the instrument is required before measurements may be taken with the instrument. Such calibration comprises additional and tedious steps that must be performed before the instrument is able to perform measurements on a Device Under Test (DUT). Such calibration typically requires the sequential physical connection of a number of predetermined loads to the VNA, and then calibrating to these reference values. Such a procedure may comprise sequentially connecting a shorted circuit, a 50 ohm circuit, and an open circuit and reading each with the VNA to provide a reference plane for the device. Once this reference plane is established, then other measurements can be taken by the VNA. Thus, after the reference plane is established, a DUT can then be connected to the VNA to take measurements therefrom. However, even at this point, the user must properly choose numerous settings of the VNA to be sure that the measurements are taken correctly. Thus, various sample rates, configuration settings, memory usage and the like must be indicated by the user. Finally, once a measurement is taken, a user may be provided with an s-parameter value for the current DUT. There is typically, however, no manner of easily storing or performing other post measurement processing of these measurements.

Therefore, in accordance with various embodiments of the invention, a SINA is provided that provides a simple yet flexible user interface system. The system in particular may allow for one click calibration and measurement, various preset configuration setting profiles for use by a user depending on desired accuracy and results, and allows for a number of post processing and reporting actions that are currently unavailable on any VNA type device. Provision of these features in such a SINA as set forth in accordance with various embodiments of this invention allows a user to quickly and easily perform testing on the DUT in a manner previously unavailable.

In a traditional s-parameter measurement instrument, such as a VNA or the like, calibration is a necessary first step to be performed before the instrument performs any DUT measurement. The SINA preferably constructed in accordance with an embodiment the invention facilitates automatic calibration as part of measurement. The instrument internally provides necessary reference measurements as noted above, thus relieving the user of the tedious task of connecting and disconnecting various reference loads for calibration.

Although performing such a calibration procedure as part of a full measurement procedure is the preferred form of an embodiment of the invention, a reduced calibration sequence may also be employed. In accordance with this reduced calibration sequence, it is also possible to first explicitly perform a full, internal calibration procedure by itself as noted above, if desired by the user, such calibration still being performed automatically by the SINA of the invention. The results of this calibration may then be stored and applied to subsequent DUT measurement procedures. The calibration settings may also be stored to disk or other memory and reloaded for future use if the network configuration is revisited, or for other future measurements by the SINA.

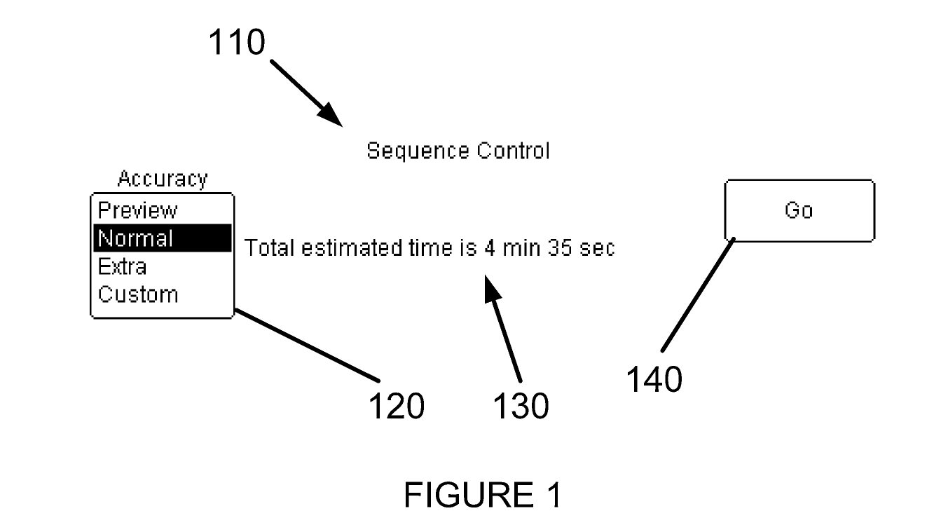

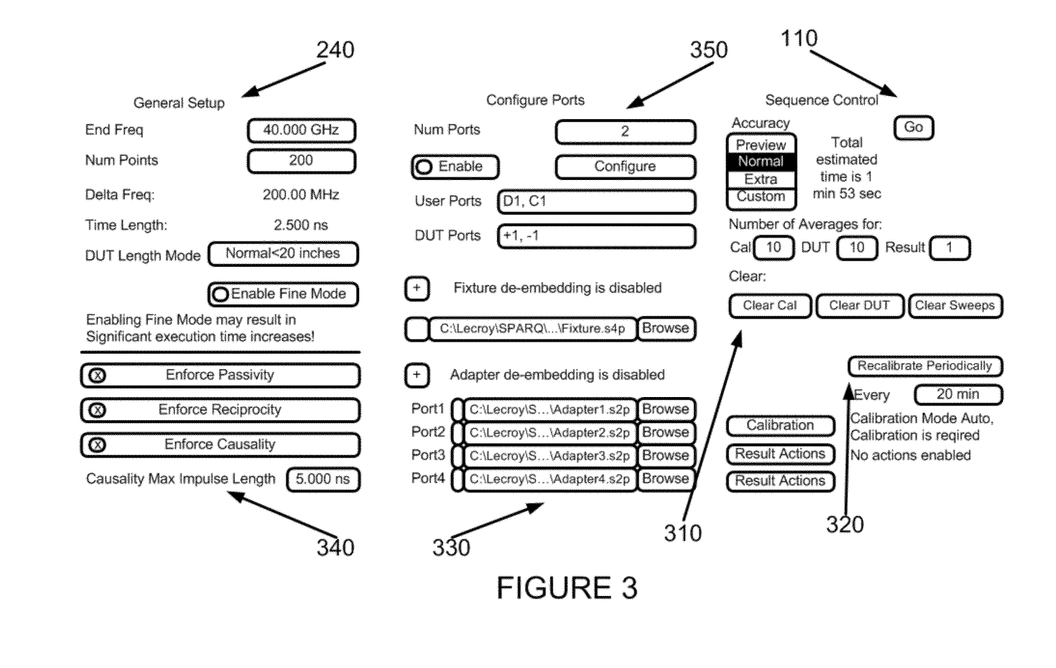

In accordance with the invention, and as is shown in FIG. 1, a SINA is thus adopted to perform a one click measurement of a DUT. The user preferably connects the DUT to the SINA and interacts with the SINA via a sequence control menu 110. The user may perform one click of a “GO” button 140 (either through a button or other selector on the user interface, through the activation of an apparatus button on a control panel or the like), and a full calibration and measurement process may take place. In response to this action, the system may execute full calibration and DUT measurement procedure without any further user intervention. As is further shown in FIG. 1, a user may also be permitted to select a desired accuracy of a measurement to be performed in accordance with accuracy sub menu 120. Each choice down the menu provides a more accurate result, but takes more time to perform, an estimated time for performing analysis in accordance with each selected accuracy setting being shown in a required time display 130. A user may prefer a less accurate scan and processing when testing to determine whether parameters are correct, etc. and then may perform a more accurate, but longer scan once the apparatus is properly setup, as will be further described below with respect to FIG. 3.

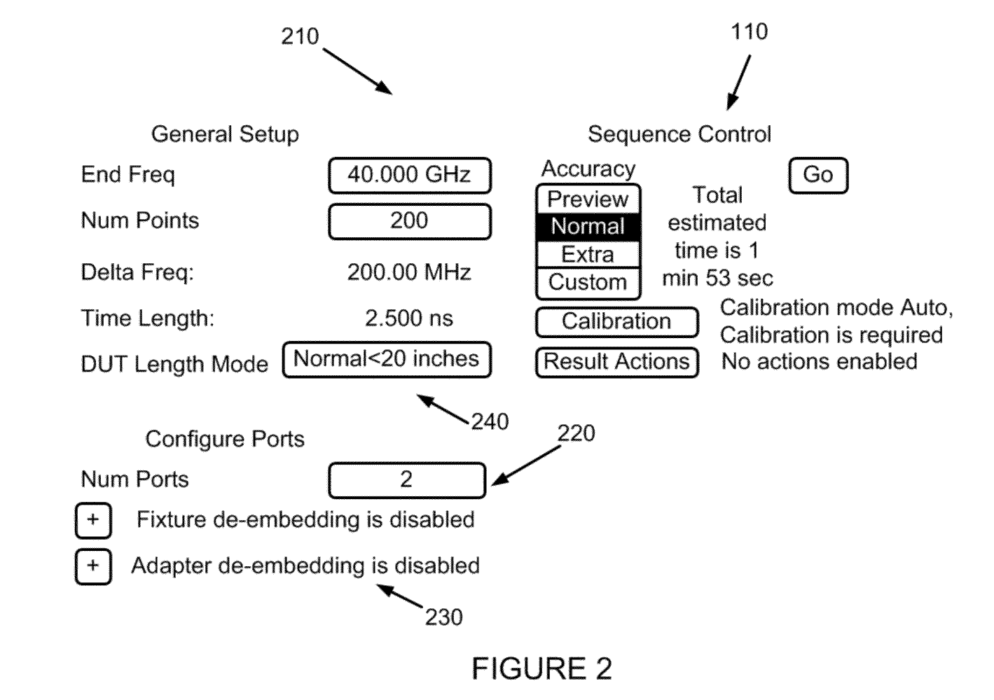

FIG. 2 depicts sequence control menu 110 of FIG. 1 as part of a main setup dialog display 210 provided in accordance with an embodiment of the invention. In addition to including sequence control menu 110, display 210 further may comprise a port configuration setting 220, a de-embedding selection menu 230 for selectively disabling fixture and/or adapter de-embedding, and a general setup menu 240.

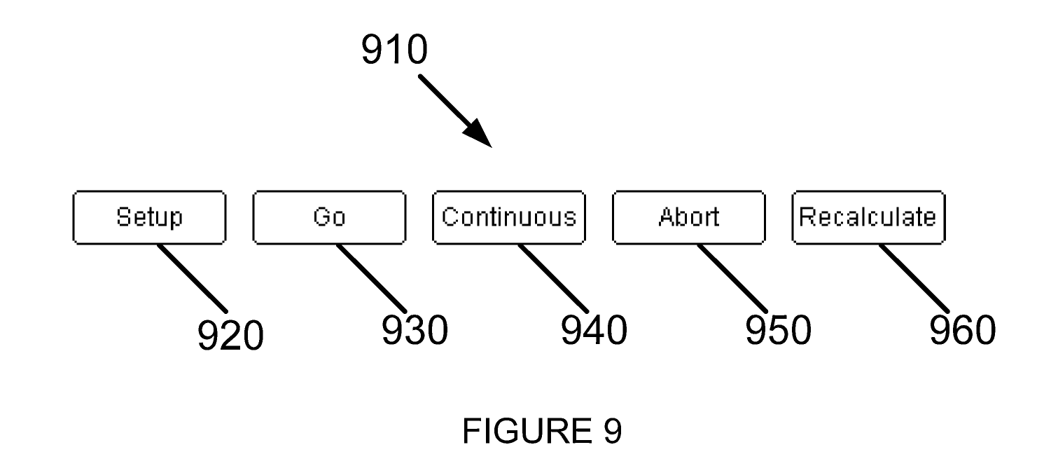

FIG. 3 depicts a more advanced setup menu in accordance with an embodiment of the invention, allowing the user to preferably perform additional non-automatically invoked functions, such as deembedding various fixtures (330), output port configuration (350), clearing of various SINA captured and/or setting data (310), setting a recalibration schedule (320), adapter and fixture de-embedding configuration (330), enforcement of various processing rules (340) and the like. Many of these configuration parameters, including timebase settings (such as End Frequency, Number of points) may be modified and applied to current measurements by performing a recalculate without re-running the measurement sequence. This has several benefits: the user may see the effects of different parameters on the same data set as well as saving the time for re-acquiring all of the measurement data. The recalculate function is provided explicitly for the user, so multiple configuration parameters may be modified before the recalculation is performed, and multiple recalculations may also be performed. The recalculate function, which is made available to the user via the Recalculate button (See FIG. 9, reference 960, as will be described below), causes a recalculation to be performed on the existing calibration and DUT measurement data. No further data is acquired during the Recalculate procedure. The recalculate procedure applies any configuration changes to the existing data to produce new s-parameter results.

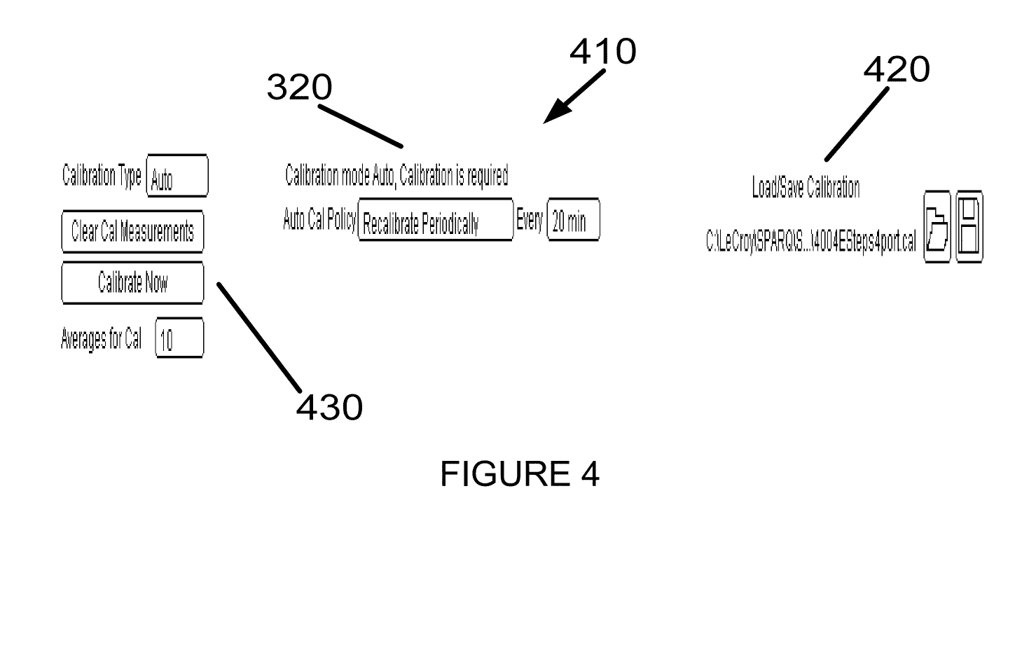

Such calibration and measurement may employ various predetermined calibration and configuration settings that are normally sufficient for nearly all measurements being performed by the SINA. If, however, a user wishes to change such configuration settings for a particular purpose, the SINA of the present invention may provide such flexibility in an easy to operate package. Thus, through the use of sequence control menu 110 a user may select from a set of various “Preset” settings such as, for example, “Preview”, “Normal”, “Extra” and “Custom”, as noted above and as shown in FIGS. 1 and 2. These settings may serve different purposes for the user, as noted above. “Preview” may provide a relatively fast measurement procedure primarily intended for verifying configuration/connections (a “sanity check”), “Extra” may provide increased accuracy using longer measurement and “Custom” may provide fully customized setting, allowing the user to fine tune any of the desired configuration settings. The “Normal” setting may preferably be used for automatic calibration and measurement if no other settings have been selected. As further noted above, while a calibration is normally preferably part of the automatic settings, a user may perform a calibration separately when desired. Such a calibration may be performed in accordance with a calibration setup menu, such as that shown in FIG. 4, and including calibration recalibration menu 320, a load/save calibration menu 420 for indicating a file to be loaded including a calibration, or a file to which a calibration is to be saved. Also included is a calibration setting menu 430 to allow for a calibration mode and various settings to be selected, including a calibration clearing selection, a calibrate now selection, and an average setting for calibration.

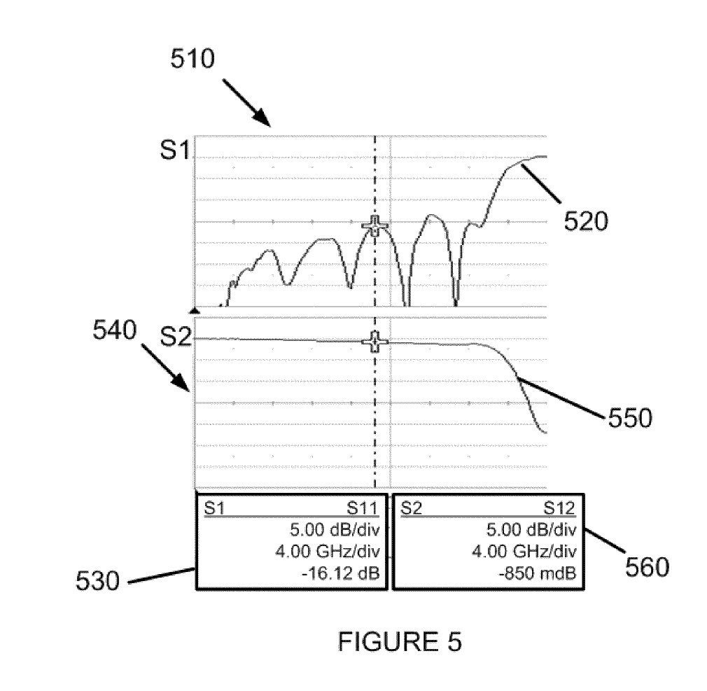

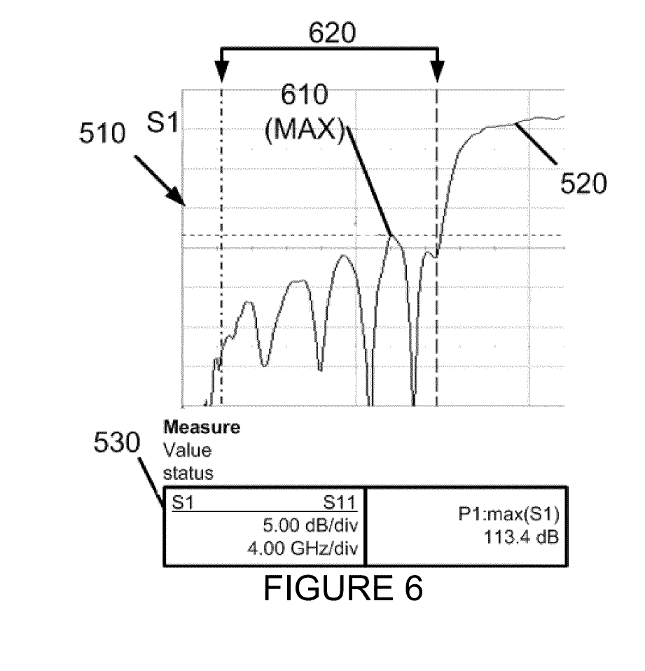

Once a measurement procedure has been completed, the SINA provided in accordance with an embodiment of the invention may provide for the s-parameter results to be displayed via charts, to be further analyzed, or to be saved to disk or emailed. Any of these procedures may be indicated to be performed automatically when the measurement procedure finishes or may be performed interactively as selected by the user. Analysis of the results data examples may include, but are not limited to, cursor measurements of magnitude or phase at specific frequencies, parametric measurements (such as min, max, mean, etc. . . . ) over the full result data or limited to regions of the result data. It is also possible to generate and analyze eye patterns resulting from the application of various standard and custom simulated signals to the DUT s-parameter results. Since the s-parameter and analysis results may be saved to disk, this analysis may be performed at a later time, or on a different device altogether. An example of such analysis of results is shown at FIG. 5, particularly depicting measuring a magnitude of an s-parameter at a specific frequency over time. Thus, as is shown in FIG. 5, a first s-parameter S1 is shown in top grid 510, and includes a curve 520 representing the value of the S1 s-parameter at a predetermined frequency for a predetermined period of time in accordance with the indicated GHz/div in menu 530. Similarly, a second s-parameter S2 is shown in top grid 540, and includes a curve 550 representing the value of the S2 s-parameter at a predetermined frequency for a predetermined period of time in accordance with the indicated GHz/div in menu 560. FIG. 6 depicts measuring a maximum value 610 for a desired parameter S1, as shown in FIG. 5, within a gated range 620 of s-parameter results.

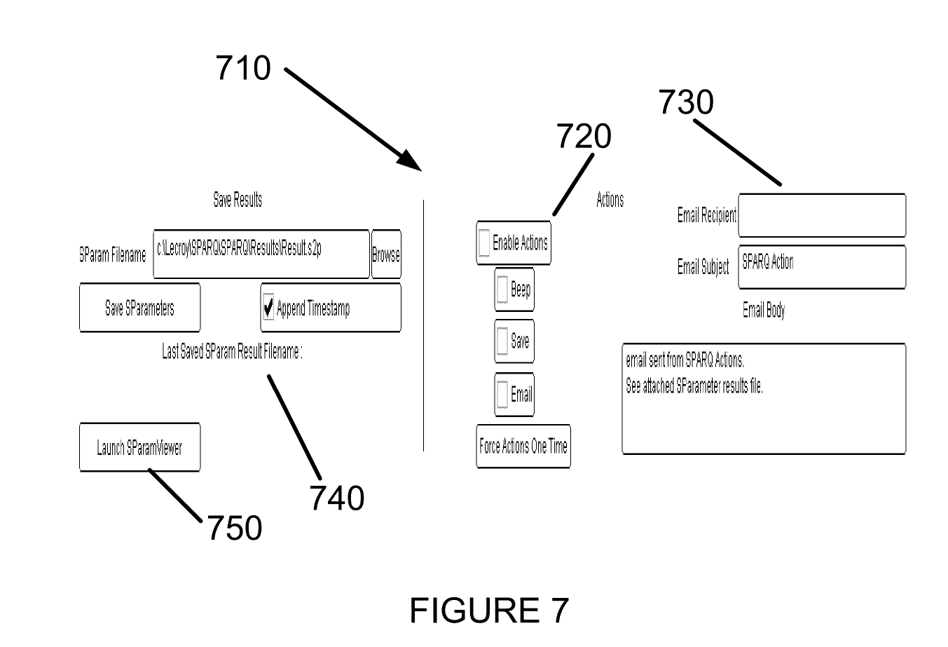

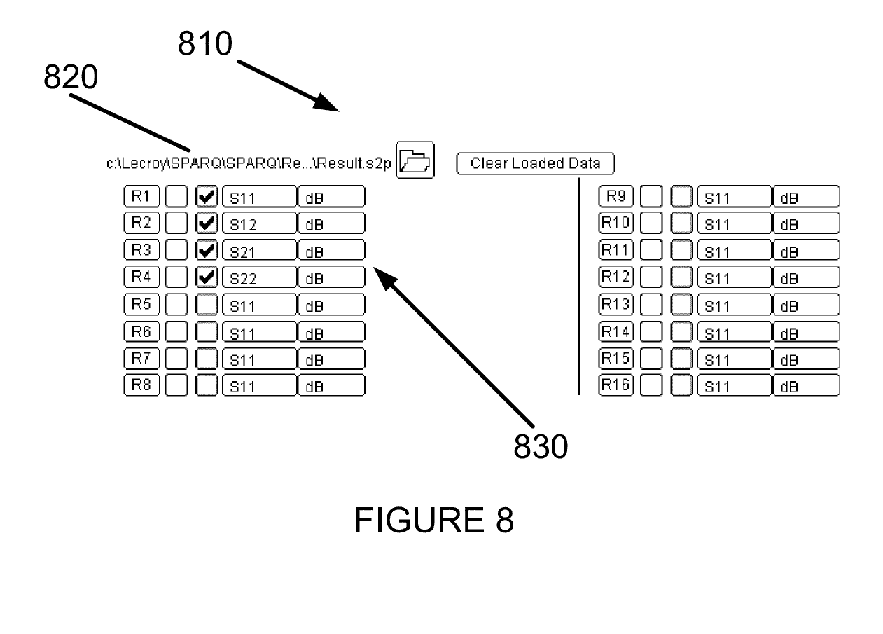

After measurements are taken by the SINA, results may be displayed in any number of desired formats. FIG. 7 depicts a results action setup menu 710, allowing the user to define one or more actions (beep, save or email in this example) to be taken upon completion of a measurement sequence or the like at a submenu 720. Email submenu 730 allows the user to indicate an email recipient, subject and text in the email body. Save submenu 740 allows the user to indicate a filename, timestamp and other information, as well as initiate saving of the s-parameters. Saved s-parameter result files may subsequently be imported for all of the same types of viewing and analysis as are available for the “live” s-parameter results. Finally, an s-parameter viewer, depicting s-parameters in formats such as those shown in FIGS. 5 and 6 may be launched from selector 750. FIG. 8 shows an s-parameter import menu 810 allowing the user to specify the s-parameter filename 820 and the configuration parameters 830 for the various imported results. The s-parameter import feature provides a way for viewing and analyzing previously saved s-parameter results; for example, comparing results from a previous measurement procedure with current measurement results. Since the s-parameter file format is preferably an industry standard, these may be files produced by measurement procedures on the SINA or any other instrument or software capable of producing s-parameter files. The user may specify the s-parameter file to import via file browser 820 and then may preferably view up to 16 results configured via the various parameters for specifying which s-parameter (S[1][1], etc. . . . ) and which type of result (magnitude, phase, step, impedance, etc. . . . ) via controls 830 on setup dialog 810. A full measurement procedure may be run explicitly one time, in response to the “Go” command, as noted above, or the measurement procedure may be run in a “continuous” mode in which the full measurement procedure will re-run automatically upon completion of a measurement sequence. In this continuous mode, any result actions (save results to disk, email results, analyze results, etc. . . . ) may be performed each time that the procedure finishes, or at some other desired interval or timing. Thus a user is able to perform sequential measurements on a DUT, with full results analysis and processing, without further user intervention. Via measurement menu 910 as shown in FIG. 9, the user can select to setup these measurement parameters at selection 920, start a measurement procedure at selection 930, switch to a continuous measurement procedure at selection 940 and may preferably select a single analysis from the same button 940 if a continuous measurement sequence is taking place, abort the continuous measurement procedure at 950, and recalculate various metrics using acquired, accumulated and processed data at selection 960, as described above.

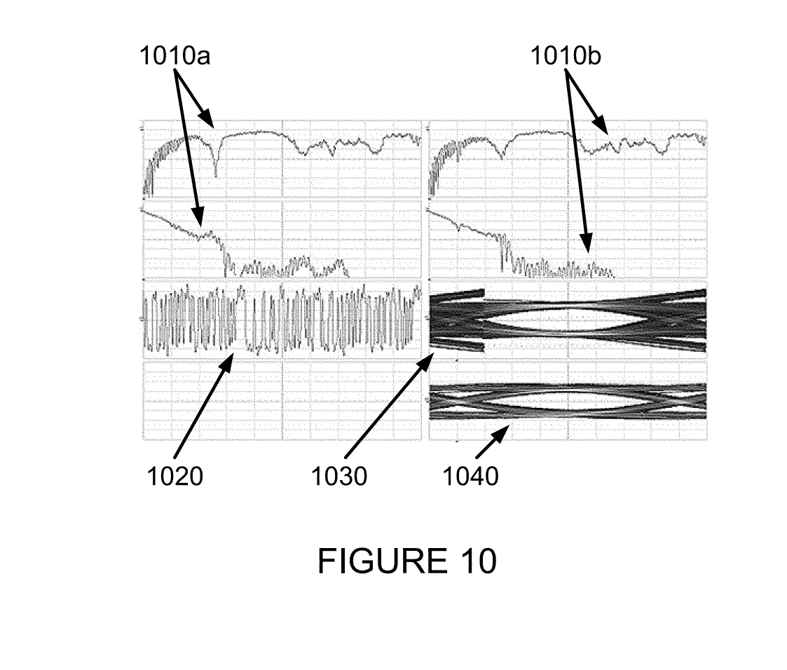

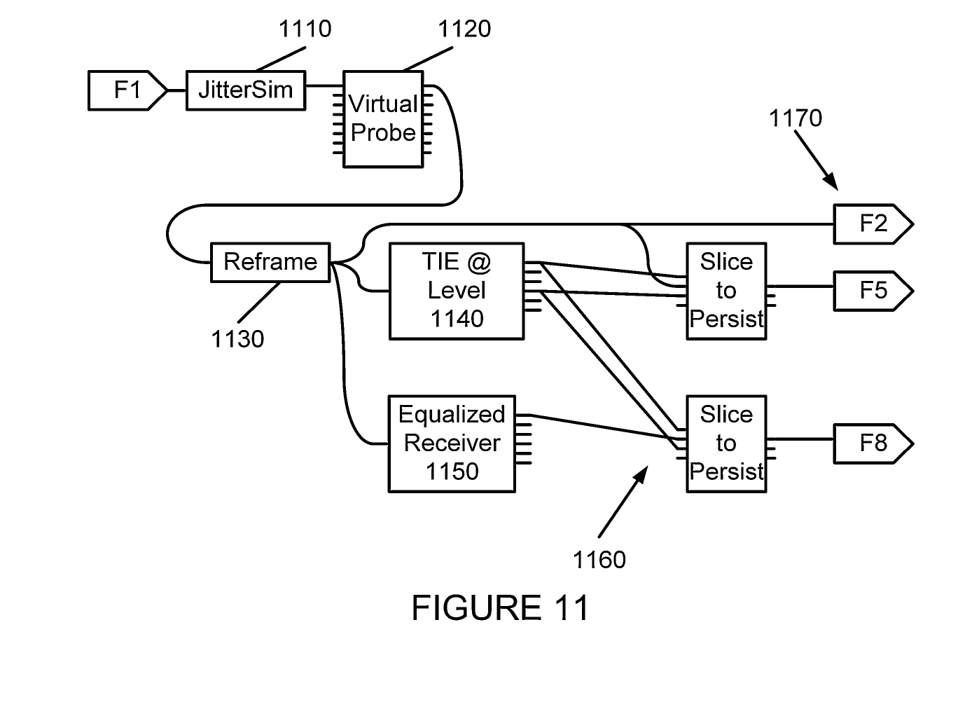

After various measurements have been made in accordance with the above described embodiments of the invention, a number of post processing and analysis features may be invoked. In one of the contemplated post processing analysis features in accordance with the invention, the result of DUT s-parameter measurement may be embedded into a measured electrical real time signal or simulated real time signal to display the effect that the DUT would have if added into the electrical circuit. Thus, the measured DUT can be embedded in a real or simulated configuration to test what effect it might have on the system. The SINA in accordance with the invention may display the result in an eye view embedding measured s-parameters as is shown in FIG. 10, or in any other desired results display mode. FIG. 10 shows s-parameters 1010a, 1010b of a serial data communication channel measured by an instrument along with the waveform result of sending a simulated pseudo-random bit sequence (PRBS) pattern through this measured channel at 1020. Also shown is the resulting eye-pattern of this signal at 1030 along with the eye-pattern of an equalized waveform used to see the interaction between the channel, equalized receiver and transmitter at 1040. Therefore, in accordance with various embodiments of the invention, it is contemplated that various analysis features, previously unavailable in a single apparatus such as a VNA or TDNA, may be initiated and employed in accordance with the inventive SINA. Such analysis may be performed on actual or simulated data, and may preferably include or exclude various system components, including the DUT. This specific analysis configuration used for producing the results of FIG. 10 is shown in FIG. 11, and will be discussed further below.

A processing web editor definition for providing such an eye view embedding the measured s-parameters is shown in FIG. 11. The same view can be used to measure various serial data properties of the signal. This feature facilitates determining the effect of the DUT directly in the form of standard serial data measurement. Once the s-parameters are embedded in such an eye diagram processing configuration, many measurement values normally performed on eye diagrams can be determined, such as a determination of jitter, and any other serial data analysis measurements. In this particular analysis configuration embodiment, a Jitter Simulation component 1110 may be used for generating simulated serial data signals with controls for various types and amounts of jitter. This component preferably drives a Virtual Probe 1120 component which is configured in part with s-parameter data which was previously measured (may be the latest saved s-parameter results of the sequencer measurements, may be previously-saved measurements or s-parameter characterization data provided from any other source). This component produces waveform results that show the effect of the DUT characterized by the s-parameters given the input waveform results from the Jitter Simulation component. Reframe component 1130 provides a rescaling of the Virtual Probe output and is fed to one of the outputs (1170 output F2). This output provides a view of the raw output waveform of the DUT (since as mentioned before, the Virtual Probe emulates the DUT as characterized by the s-parameters). This raw output waveform may then also be fed to two other processing chains for further analysis. The TIE@Level (TimeIntervalError at Level) component 1140 provides emulation of a PLL that may typically exist in a serial data circuit and provides timing measurements at its output which serve as a clock for identifying sub-waveforms within the full raw waveform. In parallel with TIE@Level 1140, an Equalized Receiver component 1150 may provide emulation of several other important serial data circuits that improve the recovery of serial data. Both of these parallel paths are then fed to respective SliceToPersist components 1160 which split the full raw waveform into sub-waveforms as specified by the timing measurements from TIE@Level 1140 which emulates the PLL. These sub-waveforms may then be plotted on top of each other in a persistence map, thus producing the eye diagrams: 1170 F5 output being the unequalized eye diagram and 1170 F8 output being the equalized eye diagram. This particular embodiment of the invention shows the use of the simulated input waveforms but it is also possible to provide acquired waveforms as the input; either via live acquisition system or waveforms saved on another acquisition system and imported into this processing configuration. The various processing components may be configured as per their control settings to provide variations in the analysis (e.g. turning on/off different types of equalization, configuring parameters that affect the amount/quality of the equalization, increasing/decreasing the amount of simulated jitter, etc. . . . ). Thus, in accordance with embodiments of the invention, the SINA may perform various signal serial data analysis measurements and functions, may perform various de-embedding functions, may allow for the implementation of various virtual probing functions, and in other ways allows for one or more of the following from a single user interface, and preferably in a single apparatus: characterize a DUT, measure a channel, acquire a waveform, and shows various effects of the waveform and the apparatus. Such a single interface may also be employed to operate a number of interconnected devices performing one or more of the desired functions.

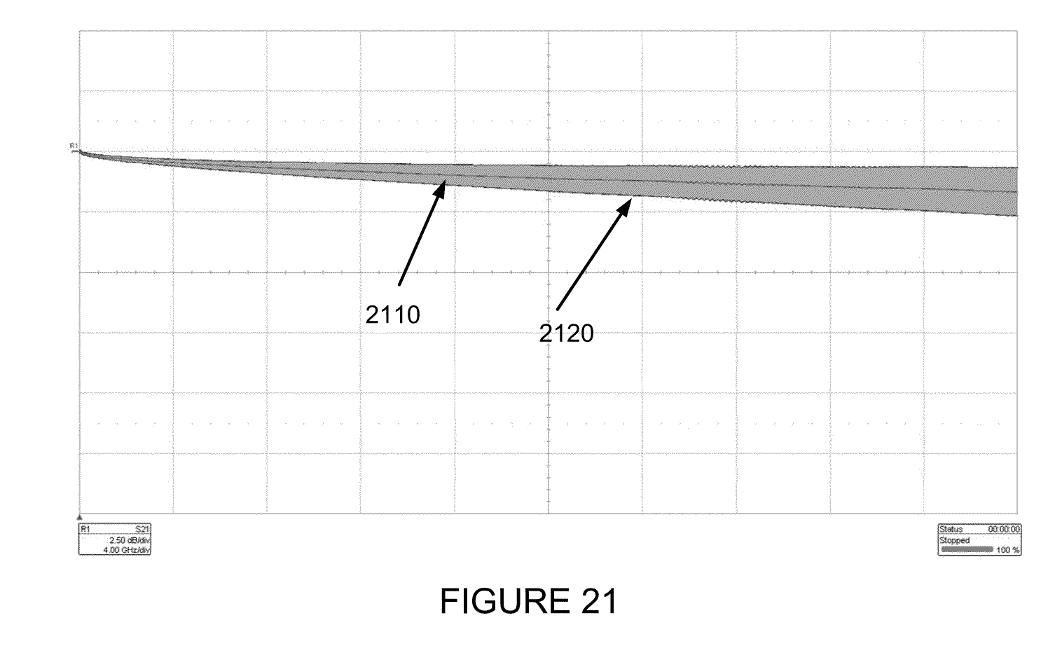

Any typical measurement instrument contains different sources of errors such as electrical noise, calculation error and calibration error. The SINA constructed in accordance with various embodiments of the invention is no different in this respect. In accordance with an additional embodiment of the invention, however, an estimation of such error may be made (such error estimation being determined in accordance with one or more procedures as set forth in copending U.S. Provisional Patent Application 61/300,065 titled “Time Domain Network Analyzer”, filed Feb. 1, 2010, by Pupalaikis, et al. and may be displayed as a confidence curve or interval in a graphical form for the end user. As is shown in FIG. 21, confidence curve 2120 may be displayed as an overlap view on top the actual s-parameter measurement 2110 or on separate axis on the same grid view if desired. The confidence curve 2120 indicates to the user the confidence or the amount of estimated error of the s-parameter measurement. Thus, an error band, or other standard deviation of error may be displayed to the user, thus providing an indication of the confidence of the accuracy of the measured values.

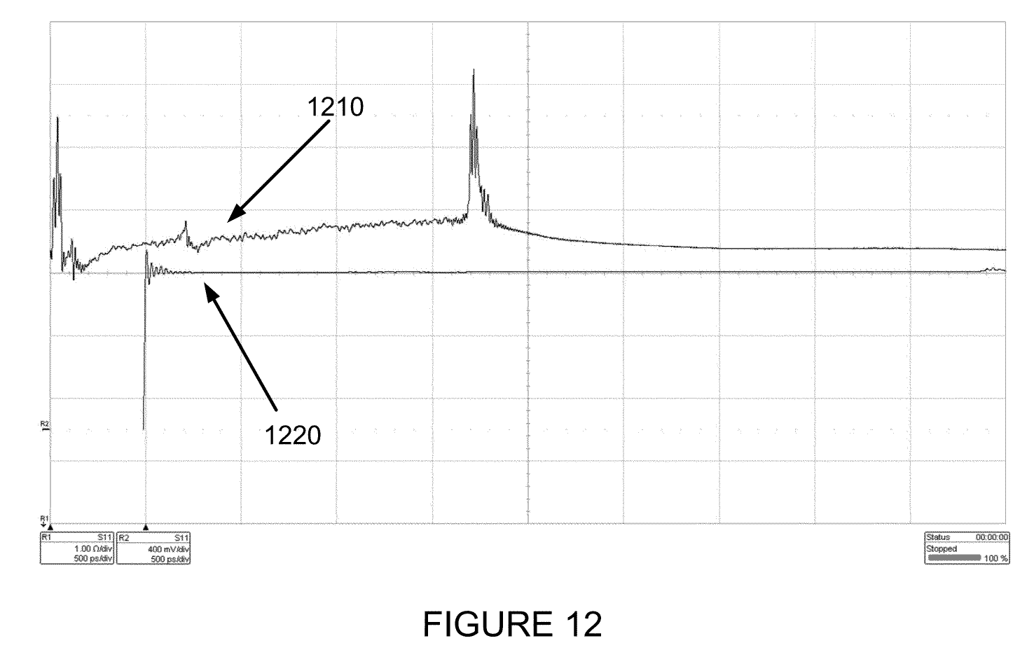

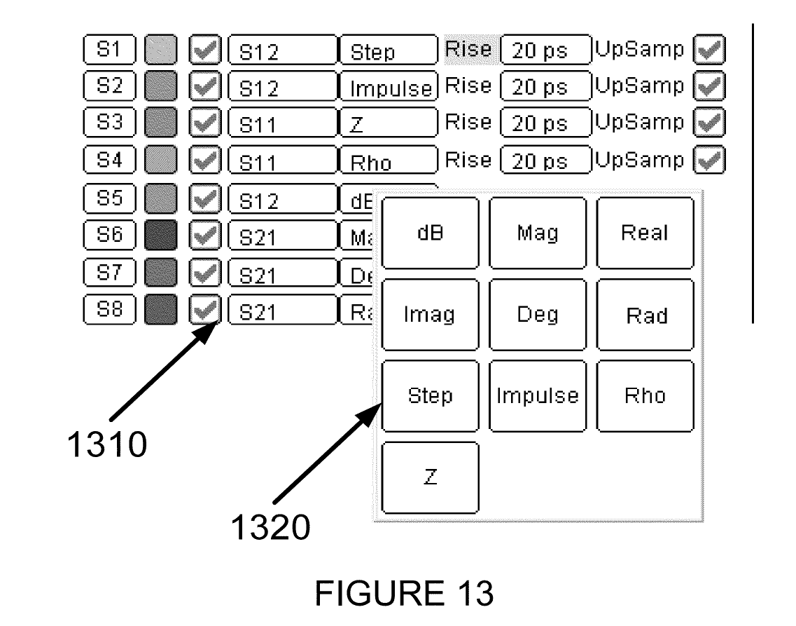

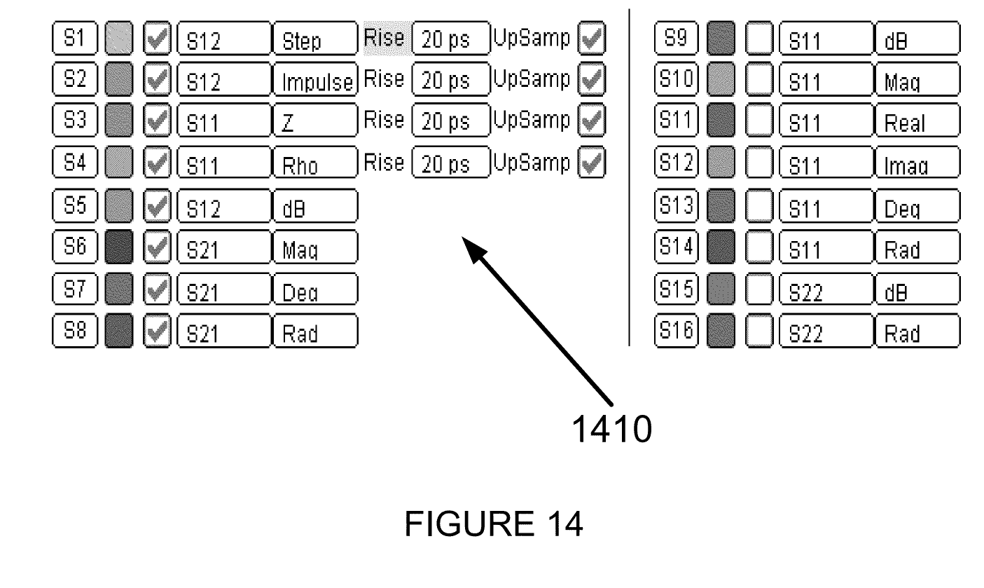

In addition to the above post processing, in accordance with the invention, the inventive SINA may use the result of a DUT s-parameter measurement and calculate a normalized (calibrated) TDR pulse 1220. This view, as shown at 1210 in FIG. 12, preferably reflects an approximation of the impedance profile of the DUT over time. If the velocity of propagation is known, then the impedance profile indicates how the characteristic impedance of the DUT changes with the length of the DUT. A PCB manufacturer or other interested party, for example, may look at the impedance profile of the signal trace and verify if the trace is built according to design. The s-parameter result 1310 may be configured as different time domain types: step response, impulse response, impedance (Z) or rho, as well as various frequency domain types, as shown in configuration menu 1320 of FIG. 13. Multiple s-parameter result views are available, so these different time and frequency domain results may be viewed and analyzed concurrently. FIG. 14 shows a results display setup menu 1410, allowing a user to display preferably up to 16 different views, each showing different selected s-parameters from among the group of measured s-parameters as shown in FIG. 14.

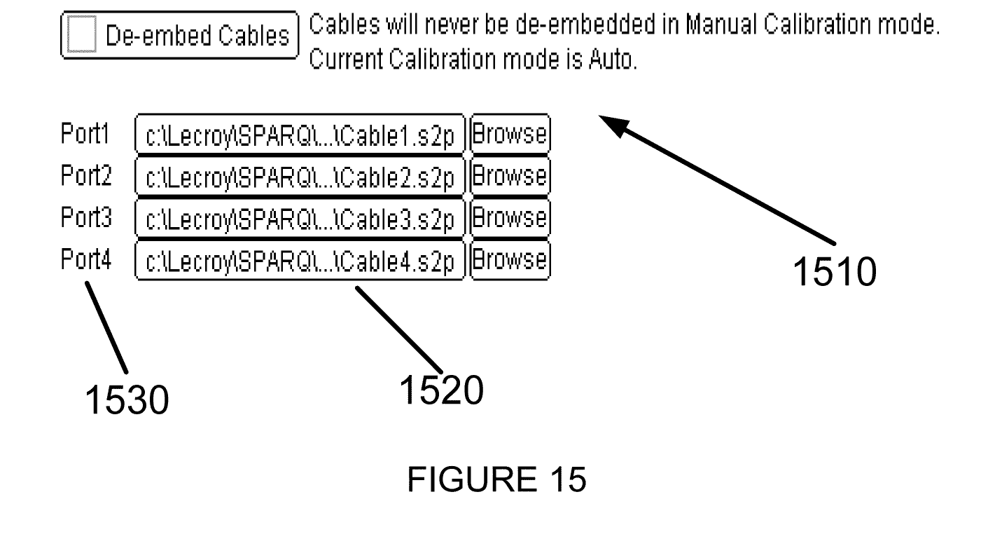

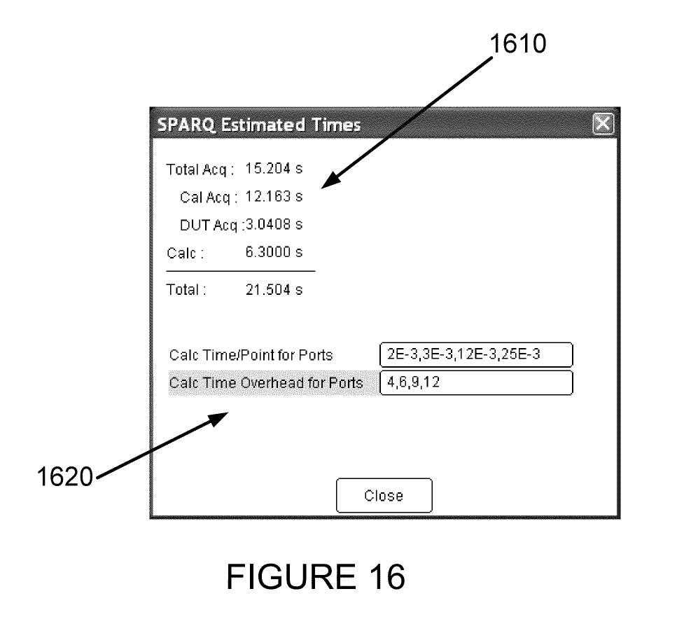

In accordance with yet another embodiment of the invention, a user may be provided with an instrument setup display 1510, as set forth in FIG. 15, for indicating a location of s-parameter files 1520 associated with particular cables or other devices associated with various ports 1530 the test and measurement apparatus, and the ability to de-embed cables from the measurements. The cable de-embedding feature provides the user with the ability to essentially remove the effects of the cables on the measurement results for the DUT. This is accomplished by characterizing the cables via s-parameter files, which may be provided with the cables delivered with the SINA or other cable manufacturer, or the user may even provide them. The s-parameter files which contain the characterization data for each cable are specified via the file browsers 1520. The de-embedding procedure may either be enabled or disabled via the “De-embed Cables” checkbox in FIG. 15. FIG. 16 depicts a sub menu for providing a further break down of estimated processing time shown in the sequence control portion of FIG. 2. Thus, the user is able to determine what functions are attributable to which portions of estimated processing time. While a number of sub times are shown, including Total acquisition time, calibration acquisition time, DUT acquisition time and calculation time in calculation 1610, and an indication of the calculation time required for both the calculation of points and overhead for the various ports of the SINA at 1620, in accordance with the invention, a number of these times may be further broken down to provide additional insight to the user.

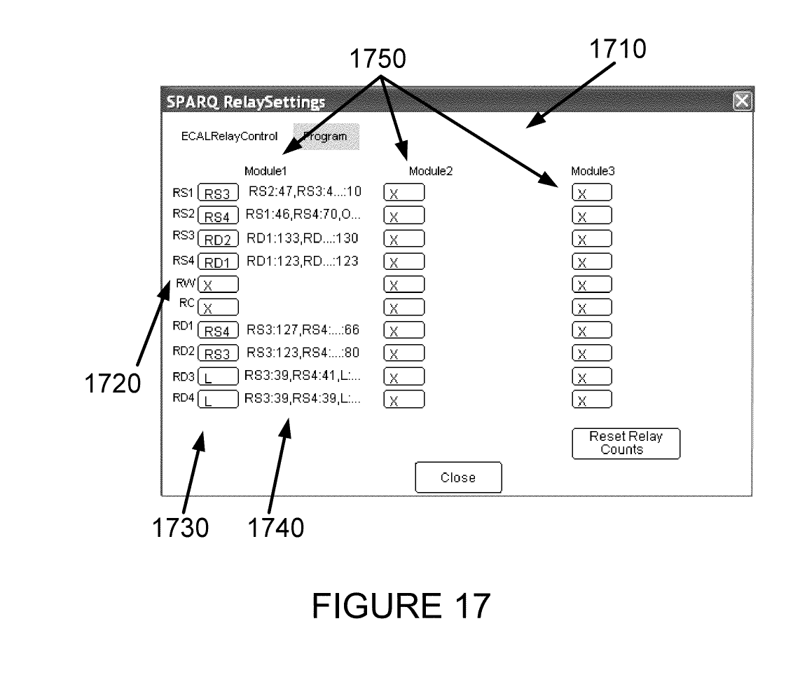

FIG. 17 provides a relay settings display 1710, allowing a user to determine and/or specify which relays 1720 are in use in the system (normally such relay inclusion is set automatically) and how relays 1720 are configured 1730 in the system (normally such relays are configured automatically). Such display further may be adapted to count a number of uses of each of the one or more relays in accordance with a particular measurement procedure, or over the history of use of the apparatus, thus preferably tracking an overall usage of the various relays in the apparatus. These counts are preferably maintained separately for each relay position of each relay and may be shown as a comma-separated list of “position:count” 1740. The system may further be composed of multiple modules 1750 depending on how many ports the particular instrument is able to measure. FIG. 17 depicts one possible embodiment of the invention, a 4-port system in which Modules 2 and 3 are not present.

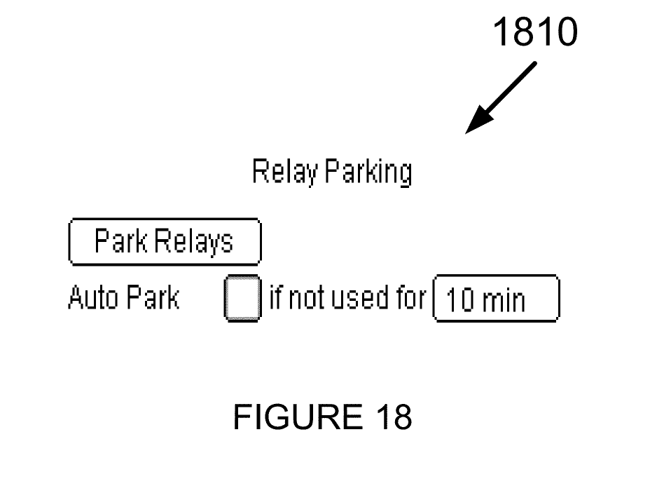

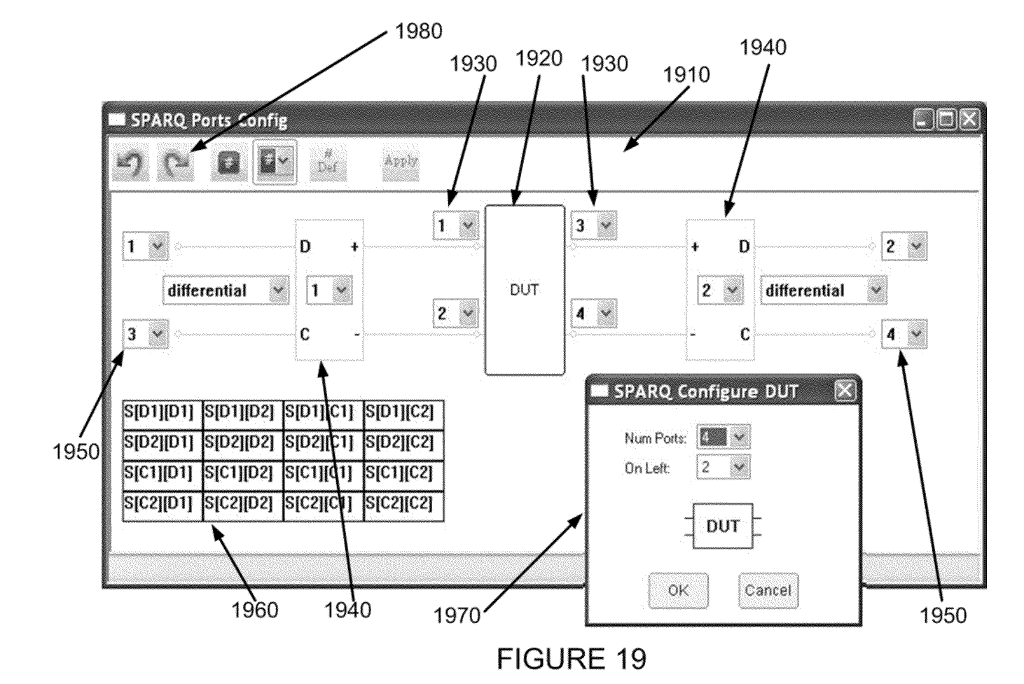

FIG. 18 shows configuration of the relay parking feature 1810 which provides control of placing the relays in a parked state such that the internal electronic circuits are better isolated from ESD. The relays may either be explicitly placed in this parked state or may be automatically parked if unused for the specified amount of time. FIG. 19 depicts a ports configuration display which provides a user with a method for determining an output format of one or more stored s-parameters. The user is able to define how various determined s-parameters will be calculated and stored, and according to particular desired port configurations and connections. The ports configuration editor presents a display panel 1910 to the user, such as that shown in FIG. 19, whereby the user may view, edit and specify a number of ports 1920 to be used in the subsequent measurements, specify which instrument ports are connected to which DUT ports 1930, which ports are expressed as single-ended or differential at selectors 1940, and the order in which those ports (1950) are stored in s-parameter results. These port specifications are shown in a preview table/matrix 1960, so that the user may quickly see how changing various ports settings will affect the s-parameter names shown in result display controls as well as the order in which they may be stored in any saved s-parameter result files. Clicking on the DUT icon 1920 in the display may present a sub-menu 1970 where the user may specify the number of ports in the measurement as well as how many ports should be shown on the left in the diagram (the remaining ports being shown on the right in the diagram). A toolbar 1980 provides undo/redo functions for any editing actions on the diagram, selection of the numbering mode for the ports (either via buttons or dropdown selectors), default numbering for a given diagram and applying the current state of the diagram to the measurement configuration. By using these various editing features on this diagram, the user is able to specify various port definitions that are more meaningful to the user's particular DUT, rather than forcing the user to an immutable specification of the port numbers. The purpose of this being to allow the user to think more in terms of the particular DUT being characterized rather than having to think in terms of the instrument characterizing the device.

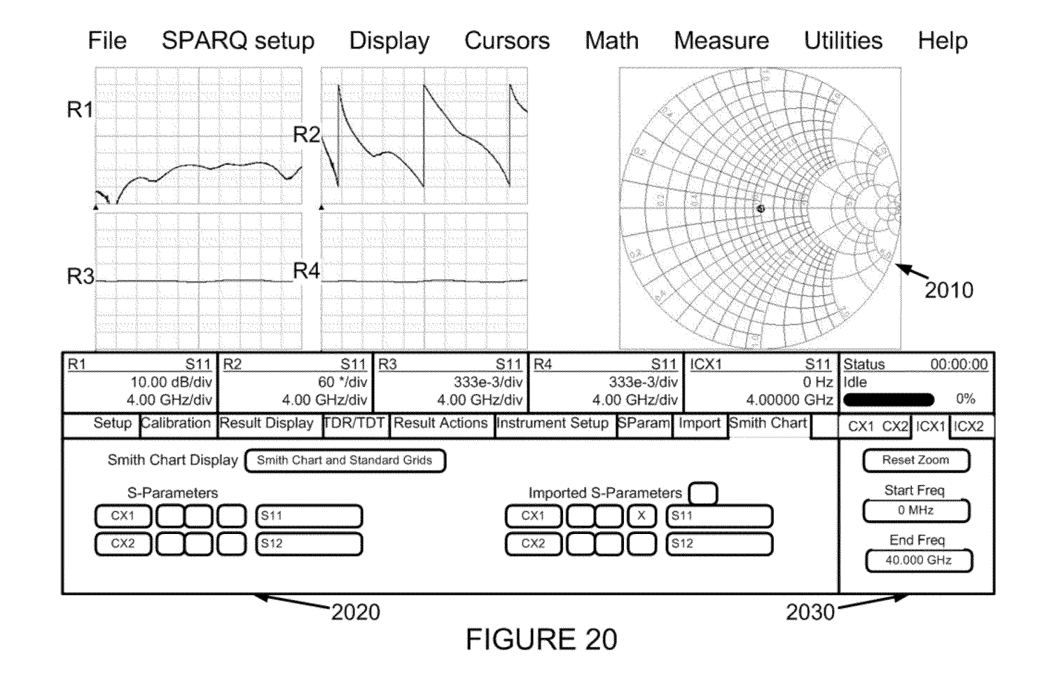

FIG. 20 depicts an alternative display in accordance with an embodiment of the invention, and in particular shows a Smith chart. Such a Smith chart can be generated in accordance with the invention by simple selection by the user. No other further user intervention is required. The Smith chart of FIG. 20 may contain results from current s-parameter measurements or imported s-parameter files. These result views are enabled/disabled via checkboxes 2020. Each result on the Smith chart may be zoomed to a specified frequency range 2030.

While the invention has been described applicable to a SINA, the invention is intended to be equally applicable to other TDNAs, network analyzers, test and measurement apparatuses and electronic apparatuses in general.

It will thus be seen that the objects set forth above, among those made apparent from the preceding description, are efficiently attained and, since certain changes may be made in the above construction(s) without departing from the spirit and scope of the invention, it is intended that all matter contained in the above description or shown in the accompanying drawing(s) shall be interpreted as illustrative and not in a limiting sense.

It is also to be understood that the description is intended to cover all of the generic and specific features of the invention herein described and all statements of the scope of the invention which, as a matter of language, might be said to fall there between.

What is claimed is:

1. A graphical user interface for use with a signal integrity network analyzer, comprising:
a selection for selectively enforcing one or more of passivity, reciprocity and causality in one or more measurements by the signal integrity network analyzer.

2. A graphical user interface for use with a signal integrity network analyzer, comprising:
a recalculate selection, wherein after analysis of a calculated waveform, one or more system parameters may be modified, and the previously acquired waveform is again analyzed without acquisition of any additional waveform data in accordance with the one or more modified system parameters.

3. The graphical user interface of claim 2, wherein the one or more modified system parameters comprises selection of embedding or de-embedding one or more system fixtures.

4. The graphical user interface of claim 3, wherein the selection of de-embedding selectively de-embeds one or more cables.

5. The graphical user interface of claim 3, wherein the selection of de-embedding selectively embeds one or more simulated system fixtures.

6. The graphical user interface of claim 5, wherein an acquired waveform is analyzed including the effects of the embedded one or more simulated system fixtures.

7. The graphical user interface of claim 2, further comprising a selection for modifying one or more system parameters after analysis of a waveform, wherein upon selection of the recalculate selection, the previously acquired waveform is reanalyzed without acquisition of any additional waveform data in accordance with the one or more modified system parameters.

8. The graphical user interface of claim 2, wherein the one or more modified system parameters comprises a selection for selectively enforcing one or more of passivity, reciprocity and causality in one or more measurements by the signal integrity network analyzer.

9. The graphical user interface of claim 2, wherein the one or more modified system parameters comprises a selection for selectively configuring one or more output ports.

10. A graphical user interface for use with a signal integrity network analyzer comprising:
a selection for configuring a number of ports for a device under test to be employed by the signal integrity network analyzer.

11. The graphical user interface of claim 10, further comprising a selection for selecting one or more of a mixed mode and a single mode s-parameter calculation for the device under test by the signal integrity network analyzer.

12. The graphical user interface of claim 11, wherein the configured ports are displayed graphically.

13. The graphical user interface of claim 11, where an s-parameter matrix corresponding to a selected configuration of ports is displayed.

14. A graphical user interface for use with a signal integrity network analyzer, comprising:
a selection for autoparking one or more relays associated with the signal integrity network analyzer.

15. The graphical user interface of claim 14, further comprising a display for displaying a current status of one or more of the relays associated with the signal integrity network analyzer.

16. The graphical user interface of claim 15, wherein the current status includes display of a number of relay actuations of each of the one or more relays.

17. The graphical user interface of claim 14, further comprising a selection for parking one or more of the one or more relays.
